(19) United States
(12) Patent Application Publication
(10) Pub. No.: US 2016/0246139 A1
(43) Pub. Date: Aug. 25, 2016

(54) LIQUID CRYSTAL PANEL SUBSTRATE AND MANUFACTURING METHOD THEREOF

(71) Applicant: Shenzhen China Star Optoelectronics Technology Co., Ltd., Shenzhen, Guangdong (CN)

(72) Inventor: Zijian Li, Shenzhen, Guangdong (CN)

(73) Assignee: Shenzhen China Star Optoelectronics Technology Co., Ltd., Shenzhen, Guangdong (CN)

(21) Appl. No.: 14/418,606

(22) PCT Filed: Jan. 16, 2015
(86) PCT No.: PCT/CN2015/070838

§ 371 Date: May 9, 2016

(30) Foreign Application Priority Data
Dec. 31, 2014 (CN) 201410852369.5

(51) Int. Cl. G02F 1/1362; H01L 29/786; H01L 27/12

(52) U.S. Cl. CPC G02F 1/136209; H01L 27/1222; H01L 27/1285; H01L 29/78678; H01L 29/78633; G02F 2001/133302

(57) ABSTRACT

A liquid crystal panel substrate and manufacturing method thereof are provided. The substrate comprising a glass substrate, a light shielding layer arranged on the glass substrate, and an active layer arranged on the light shielding layer. Interference from unnecessary light source can be significantly decreased through the above structure of the liquid crystal panel substrate, so that the defect of photo-generated leakage current of the substrate can be alleviated, whereby the basic performance of the liquid crystal panel substrate can be guaranteed, and the problems of flickers and crosstalk of the pictures happened to the liquid crystal display can be eliminated.

### CROSS REFERENCE TO RELATED APPLICATION

The present application claims benefit of Chinese patent application CN 201410852369.5, entitled “A Liquid Crystal Panel Substrate and A Manufacturing Method Thereof” and filed on Dec. 31, 2014, the entirety of which is incorporated herein by reference.

### TECHNICAL FIELD

The present disclosure relates to the technical field of liquid display, and in particular to a liquid crystal panel substrate and a manufacturing method thereof.

### TECHNICAL BACKGROUND

A liquid crystal display device has the advantages of high definition, small size, light weight, low voltage driving, low power consumption, and the like. Liquid crystal display device is widely applied to various IT digital products, such as automobile navigation systems, engineering workstations, monitors, portable information terminals, electronic terminals, electronic books, laptop computers, and large-size direct-viewing flat panel televisions, and the like.

A thin-film transistor is an important component of the liquid crystal display device. Exposure of the thin-film transistor to unnecessary external light rays during use will cause an internal current thereof to increase, rendering a photo-generated leakage current phenomenon. The photo-generated leakage current causes the current of the thin-film transistor when the backlight is turned on to be larger than that when it is turned off, which not only affects the efficiency of the thin-film transistor, but also causes problems, such as flickers and crosstalk, to the liquid crystal display device.

Based on the above problems, a liquid crystal panel substrate used for manufacturing a thin-film transistor is urgently needed, so that the photo-generated leakage current of the thin-film transistor can be effectively alleviated.

### SUMMARY OF THE INVENTION

The technical problem to be solved by the present disclosure is to eliminate the defect of photo-generated leakage current of a thin-film transistor of a liquid crystal panel in the prior art. In order to solve the above problem, a liquid crystal panel substrate is first provided according to an embodiment of the present disclosure. The defect of the photo-generated leakage current therein can be effectively alleviated through a thin-film transistor manufactured using the liquid crystal panel substrate according to the present disclosure.

The substrate according to the present disclosure comprises a glass substrate, a light shielding layer arranged on the glass substrate, and an active layer arranged on the light shielding layer.

According to an embodiment of the present disclosure, the light shielding layer comprises a photoresist layer, the material of the photoresist layer being selected from a group consisting of amorphous silicon, polycrystalline silicon, colored nonmetallic silicides, or any combination of the aforesaid materials.

According to an embodiment of the present disclosure, the light shielding layer further comprises a first isolating layer, the first isolating layer being disposed between the photoresist layer and the active layer.

According to an embodiment of the present disclosure, the first isolating layer, photoresist layer, and the active layer have the same pattern.

According to an embodiment of the present disclosure, the substrate further comprises a second isolating layer, the second isolating layer being disposed between the glass substrate and the light shielding layer.

According to an embodiment of the present disclosure, the second isolating layer, light shielding layer, and the active layer are formed through one-time continuous film formation.

A method of manufacturing a liquid crystal panel substrate is further proposed according to the present disclosure, comprising: forming a light shielding layer on a glass substrate; forming an active layer on the light shielding layer; and performing etching on the active layer and the light shielding layer, and obtaining the liquid crystal panel substrate.

According to an embodiment of the present disclosure, the step of forming the light shielding layer on the glass substrate comprises: forming a photoresist layer on the glass substrate, the material of the photoresist layer being selected from a group consisting of amorphous silicon, polycrystalline silicon, colored nonmetallic silicides, or any combination of the aforesaid materials; and forming a first isolating layer on the photoresist layer.

According to an embodiment of the present disclosure, the method comprises forming a second isolating layer on the glass substrate prior to forming the light shielding layer thereon.

According to an embodiment of the present disclosure, the step of forming the active layer on the light shielding layer comprises: forming an amorphous silicon layer on the light shielding layer; and performing annealing treatment on the amorphous silicon layer, and forming the active layer.

In the liquid crystal panel substrate according to the present disclosure, a light shielding layer, which can effectively eliminate the influence of unnecessary light source on the active layer, is disposed between the glass substrate and the active layer. As compared with the prior art, the interference from unnecessary light source can be significantly decreased through such a structure of the liquid crystal panel substrate, so that the defect of the photo-generated leakage current of the substrate can be alleviated, whereby the performance of the liquid crystal panel substrate can be guaranteed, and the problems of flickers and crosstalk of the liquid crystal display device be eliminated.

According to the method of manufacturing a liquid crystal panel of the present disclosure, the light shielding layer and the active layer can be etched in a same irradiation procedure, so that the light shielding layer and the active layer can have the same pattern. According to the above etching procedure, the number of photomasks used therein can be reduced. Therefore, the etching procedure can be simplified, and the difficulty and cost for manufacturing the substrate can be reduced.

However, in actual manufacturing process, it is inevitable that the glass substrate is mixed with impurities, such as water vapor. The impurities will spread to and influence other layers, such as the light shielding layer and the active layer, under high temperature. In order to eliminate the above defect, a liquid crystal panel substrate, comprising a second isolating layer disposed between the glass substrate and the light shielding layer thereof, is further provided according to the present disclosure. With the second isolating layer, the impurities in the glass substrate can be effectively prevented from spreading to the light shielding layer and the active layer, whereby interference of the impurities on the light shielding layer and the active layer can be avoided, and favorable performance of the liquid crystal panel substrate can be guaranteed.

According to the method of manufacturing a liquid crystal panel of the present disclosure, in the procedure of etching the light shielding layer and the active layer, the second isolating layer is not etched. Thus, the second isolating layer can effectively cover the glass substrate, so that impurities in the glass substrate, such as ions and water vapor, can be blocked to the largest extent. As a result, the interference on the light shielding layer and the active layer can be reduced.

Other features and advantages of the present disclosure will be further explained in the following description and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

In order to illustrate the technical solutions of the examples of the present disclosure more clearly, the accompanying drawings needed for describing the examples will be explained briefly. In the drawings:

FIG. 1 schematically shows a structure of a liquid crystal panel substrate according to an example of the present disclosure,

FIG. 2 shows a flow diagram for manufacturing the liquid crystal panel substrate of FIG. 1 according to an example of the present disclosure, and

FIG. 3 schematically shows a structure of a liquid crystal panel substrate according to another example of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It should be noted that, as long as there is no conflict, all the technical features mentioned in all the embodiments may be combined together in any manner, and the technical solutions obtained in this manner all fall within the scope of the present disclosure.

Meanwhile, in the following description, numerous details are expounded for the purpose of clarification, so that examples in the present disclosure can be fully understood. However, it is obvious for those skilled in the art that the present disclosure can also be implemented without the details or specific manners described herein.

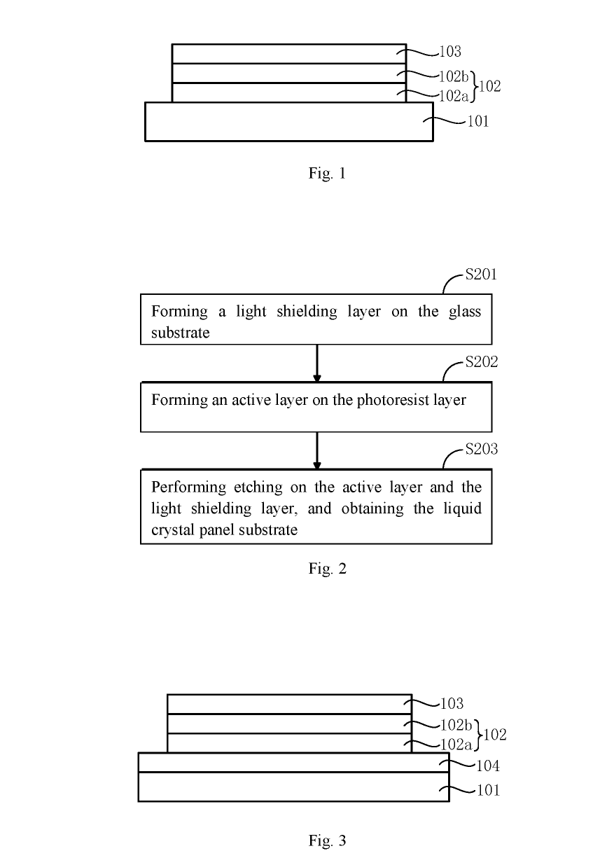

FIG. 1 schematically shows a structure of a liquid crystal panel substrate according to an example of the present example.

As shown in FIG. 1, the liquid crystal panel substrate according to the present example comprises a glass substrate 101, a light shielding layer 102, and an active layer 103. The light shielding layer 102 is arranged between the glass substrate 101 and the active layer 103. As the glass substrate 101 has a light transmittance property, when a backlight of the liquid crystal display is turned on, light rays emitted from the backlight penetrate the glass substrate 101 and irradiate the light shielding layer 102. The light shielding 102 has relatively high light resistance efficiency, thus the light rays transmitted therethrough can be effectively reduced, whereby the light rays irradiating the active layer 103 can be effectively reduced. Therefore, when components, such as a thin-film transistor, formed with said substrate is exposed to unnecessary external light source, such as the backlight source of the liquid crystal panel, the light shielding layer of the substrate can prevent the light rays emitted by the unnecessary light source from irradiating the active layer, whereby the defect of photo-generated leakage current can be effectively alleviated.

In order to achieve a better light shielding effect, as shown in FIG. 1, the light shielding layer 102 according to the present example comprises a photoresist layer 102a and a first isolating layer 102b. The photoresist layer 102a is arranged on the glass substrate 101, and the first isolating layer 102b is arranged on the photoresist layer 102a. When the photoresist layer 102a is exposed to light, free particles will be generated, which, however, can be effectively absorbed by the first isolating layer 102b. With the above structure of the light shielding layer, not only favorable light shielding effect can be achieved, the free particles generated thereon can also be prevented from spreading to the external areas. Therefore, the active layer can be free from interference from the free particles.

According to the present example, the photoresist layer 102a is made from amorphous silicon, and the first isolating layer 102b from silicon oxide. It should be noted that according to another example of the present disclosure, the photoresist layer 102a and/or the first isolating layer 102b can also be made from other suitable materials. The present disclosure is not limited to the abovementioned materials. For instance, according to an example of the present disclosure, the material of the photoresist layer 102a can be selected from a group consisting of amorphous silicon, polycrystalline silicon, colored nonmetallic silicides, or any combination of the aforesaid materials, and the material of the first isolating layer 102b can be selected from silicon nitride or silicon oxide, or the combination of the two.

Further, in another example according to the present disclosure, the first isolating layer 102b can also be configured in a multilayer structure, i.e., the first isolating layer 102b can be formed by a plurality of material layers with isolating function. The present disclosure is not limited to the above structure.

In the present example, the active layer 103 is made from polycrystalline silicon. Of course, in another example according to the present disclosure, the active layer 103 can also be made from other suitable materials, which should not be construed as limitation to the present disclosure.

FIG. 2 shows a flow diagram for manufacturing the liquid crystal panel substrate of FIG. 1 according to the present disclosure.

As shown in FIG. 2, according to the method of the present example, firstly, in a step S201, a light shielding layer 102 is formed on a glass substrate 101. Subsequently, in a step S202, an active layer 103 is formed on the light shielding layer 102. At last, an etching process is performed on the active layer 103 and the light shielding layer 102, so that the required liquid crystal panel substrate is obtained. The liquid crystal panel substrate can be used in the subsequent steps to form a thin-film transistor and other components.

In the present example, the light shielding layer 102 comprises the photoresist layer 102a and the first isolating layer 102b. In this case, in the process of forming the light shielding layer 102 in the step S201, a photoresist layer 102a is firstly formed on the glass substrate 101, and subsequently a first isolating layer 102b is formed on the photoresist layer 102a.

According to the method of the present example, in the process of forming the active layer 103, an amorphous silicon layer is firstly formed on the light shielding layer 102, and subsequently a laser annealing is performed on the amorphous silicon layer, so that the amorphous silicon layer can be converted to a polycrystalline silicon layer, whereby the required active layer 103 is formed.

According to the present example, in the process of laser annealing on the amorphous silicon layer, thin laser directional crystallization technology is adopted. However, in another example according to the present disclosure, other proper technologies, such as excimer laser annealing technology or sequential lateral solidification laser annealing technology, can also be used instead, which should not be construed as limitations to the present disclosure. Moreover, in another example according to the present disclosure, the light shielding layer 102 can also be formed from other materials using other proper technologies. The present disclosure is not limited to the above.

According to the method provided in the present example, in a step S203, the light shielding layer 102 and the active layer 103 can be etched in a same irradiation procedure, whereby the light shielding layer 102 and the active layer 103 can have the same pattern. According to the above etching process, not only the number of photomasks used therein can be reduced, the etching process can also be simplified, and the difficulty and cost for manufacturing the substrate be reduced.

Of course, in another example according to the present disclosure, different photomasks can be used in the etching process on the light shielding layer 102 and the active layer 103 according to actual requirements, so that required pattern can be formed thereon. The present disclosure is not limited thereto.

According to the above description, the light shielding layer is arranged between the glass substrate and the active layer of the liquid crystal panel substrate. The light shielding layer can effectively shield the active layer from the influence from unnecessary light source. As compared with the prior art, the interference from the unnecessary light source can be significantly decreased through such a structure of the liquid crystal panel substrate, so that the defect of the photo-generated leakage current of the substrate can be alleviated. Therefore, the performance of the liquid crystal panel substrate can be guaranteed, and the problems of flickers and crosstalk of the liquid crystal display be eliminated.

However, in actual manufacturing process, it is inevitable that the glass substrate 101 would contain impurities, such as metal particles. The impurities would spread to and influence other layers, such as the light shielding layer 102 and the active layer 103, under high temperature. Therefore, in order to eliminate the above defect, as shown in FIG. 3, according to an example of the present disclosure, a second isolating layer 104 can be further disposed between the glass substrate 101 and the light shielding layer 102 of the liquid crystal panel substrate. With the second isolating layer 104, the impurities in the glass substrate 101 can be effectively prevented from spreading to the light shielding layer 102 and the active layer 103, whereby interference of the impurities on the light shielding layer 102 and the active layer 103 can be avoided, and favorable performance of the liquid crystal panel substrate can be guaranteed.

The second isolating layer 104 can be made from a mixture of silicon oxide and silicon nitride. Of course, in another example according to the present disclosure, the second isolating layer 104 can also be made from other materials, such as silicon oxide only or silicon nitride only. The present disclosure is not limited thereto.

Correspondingly, the method of manufacturing the liquid crystal panel substrate comprising the second isolating layer 104 is similar to the method shown in FIG. 2, except that the second isolating layer 104 should be formed on the glass substrate 101 prior to forming the light shielding layer 102 on the second isolating layer 104.

It should be pointed out that in the process of etching the light shielding layer 102 and the active layer 103, as shown in FIG. 3, the second isolating layer 104 is not etched. With the above structure, not only the time of etching can be reduced, so that the production efficiency can be improved, the depth of the step can also be reduced, so that a next film layer can have a better coverage. As a result, a yield can be effectively guaranteed. Further, because the second isolating layer 104 is not etched, it can block impurities in the glass substrate, such as ions and water vapors, to the largest extent, thereby the light shielding layer 102 and the active layer 104 can be free from influence, and a reliability of the elements can be improved.

According to the present example, the active layer, the light shielding layer (including the photoresist layer and the first isolating layer), and the second isolating layer of the liquid crystal panel substrate each are formed through one-time continuous film formation using a plasma-enhanced chemical vapor deposition (PECVD) process. Herein, the active layer, the photoresist layer, and the first isolating layer of the liquid crystal panel substrate according to the present example form a particular structure of a-si/SiOx/a-Si, which can facilitate the continuous film formation. The first isolating layer (made from SiOx) enables the crystallization of an upper a-Si layer to be free from influence from a lower a-Si layer, so that a desirable crystallization effect of the upper a-Si layer can be achieved. The upper a-Si layer is transformed into a polycrystalline silicon layer (i.e., the active layer) after crystallization, and the lower a-Si layer forms a photoresist layer, whereby the continuous film formation using the PECVD process can be facilitated.

It can be further seen from the above description that the photoresist layer of the liquid crystal panel substrate according to the present example is made from nonmetallic material. If the photoresist layer is made from metallic material, even though it is covered by an insulating layer, the metallic particles generated therein will spread from an interface area to the active layer. Consequently, the active layer will be contaminated by the metallic particles. In order to avoid the aforesaid problem, in an existing liquid crystal panel substrate, a photoresist layer made from metallic material is disposed over an entire surface between the second isolating layer and the glass substrate. The above structure has to be completed through two irradiating processes, which will obviously increase the difficulty and cost of manufacturing the liquid crystal panel substrate.

It should be understood that, the examples of the present disclosure are not limited to the specific structures, processing steps, or materials disclosed herein, but incorporate the equivalent substitutes of these features which are comprehensible to those skilled in the art. It should also be understood that the terms used herein are simply for the purpose of describing specific examples, which should not be construed as limitations.

“An example” or “examples” mentioned in the description means that specific features, structure, and property described in view of the examples are incorporated in at least one example of the present disclosure. Therefore, the expression “an example” or “examples” used throughout the whole text of the description does not necessarily refer to the same example.

In addition, the features, structures and characteristics described herein can be combined with one another in any other suitable way in one example or a plurality of examples. The specific details, such as materials, described herein are used for providing a comprehensive understanding of the examples of the present disclosure. However, those skilled in the art can understand that, the present disclosure may be implemented in other ways different from the specific details described herein, or may be implemented in other methods, components and materials. The structures, materials and operations known to all are not shown or described in the examples to avoid blurring various aspects of the present disclosure.

The examples hereinabove are described to interpret the principles of the present disclosure in one application or a plurality of applications. However, a person skilled in the art, without departing from the principles and thoughts of the present disclosure, can make various modifications to the forms, usages and details of the embodiments of the present disclosure without any creative work. Therefore, the protection scope of the present disclosure shall be determined by the claims.

1. A liquid crystal panel substrate, comprising:
a glass substrate,
a light shielding layer arranged on the glass substrate, and
an active layer arranged on the light shielding layer.

2. The substrate according to claim 1, wherein the light shielding layer comprises a photoresist layer, the material of the photoresist layer being selected from a group consisting of amorphous silicon, polycrystalline silicon, colored nonmetallic silicides, or any combination of the aforesaid materials.

3. The substrate according to claim 2, wherein the light shielding layer further comprises a first isolating layer, the first isolating layer being disposed between the photoresist layer and the active layer.

4. The substrate according to claim 3, wherein the first isolating layer, photoresist layer, and the active layer have the same pattern.

5. The substrate according to claim 1, wherein the substrate further comprises a second isolating layer, the second isolating layer being disposed between the glass substrate and the light shielding layer.

6. The substrate according to claim 2, wherein the substrate further comprises a second isolating layer, the second isolating layer being disposed between the glass substrate and the light shielding layer.

7. The substrate according to claim 3, wherein the substrate further comprises a second isolating layer, the second isolating layer being disposed between the glass substrate and the light shielding layer.

8. The substrate according to claim 4, wherein the substrate further comprises a second isolating layer, the second isolating layer being disposed between the glass substrate and the light shielding layer.

9. The substrate according to claim 5, wherein the second isolating layer, the light shielding layer, and the active layer are formed through one-time continuous film formation.

10. A method of manufacturing a liquid crystal panel substrate, comprising:
forming a light shielding layer on a glass substrate;
forming an active layer on the light shielding layer; and
performing etching on the active layer and the light shielding layer, and obtaining the liquid crystal panel substrate.

11. The method according to claim 10, wherein the step of forming the light shielding layer comprises:
forming a photoresist layer on the glass substrate, the material of the photoresist layer being selected from a group consisting of amorphous silicon, polycrystalline silicon, colored nonmetallic silicides, or any combination of the aforesaid materials; and
forming a first isolating layer on the photoresist layer.

12. The method according to claim 10, wherein the method comprises forming a second isolating layer on the glass substrate prior to forming the light shielding layer thereon.

13. The method according to claim 10, wherein the step of forming the active layer on the light shielding layer comprises:
forming an amorphous silicon layer on the light shielding layer; and
performing annealing treatment on the amorphous silicon layer, and forming the active layer.

14. The method according to claim 11, wherein the step of forming the active layer on the light shielding layer comprises:
forming an amorphous silicon layer on the light shielding layer; and
performing annealing treatment on the amorphous silicon layer, and forming the active layer.

15. The method according to claim 12, wherein the step of forming the active layer on the light shielding layer comprises:
forming an amorphous silicon layer on the light shielding layer; and
performing annealing treatment on the amorphous silicon layer, and forming the active layer.
